(19) United States
(12) Patent Application Publication
(10) Pub. No.: US 2025/0063869 A1
(43) Pub. Date: Feb. 20, 2025

(54) OPTOELECTRONIC SEMICONDUCTOR COMPONENT AND OPTOELECTRONIC ARRANGEMENT HAVING SAME

(71) Applicant: ams-OSRAM International GmbH, Regensburg (DE)

(72) Inventor: Hubert Halbritter, Dietfurt (DE)

(21) Appl. No.: 18/721,565

(22) PCT Filed: Nov. 28, 2022
(86) PCT No.: PCT/EP2022/083493

§ 371 Date: Jun. 18, 2024

(30) Foreign Application Priority Data
Dec. 21, 2021 (DE) 10 2021 133 999.5

(51) Int. Cl. H01L 33/60; H01L 25/075

(52) U.S. Cl. CPC H01L 33/60; H01L 25/0753

(57) ABSTRACT

In an embodiment an optoelectronic semiconductor component includes at least one lamella with a longitudinal axis extending along an imaginary straight line and an electrically conductive main body with a recess, wherein the lamella includes a first semiconductor region of a first conductivity, a second semiconductor region of a second conductivity and an active region arranged between the first and the second semiconductor region, the active region being configured to emit a first electromagnetic radiation, wherein the lamella is arranged at least partially in the recess, and wherein the lamella has a length along the longitudinal axis which, within a manufacturing tolerance, corresponds to half a wavelength or an integer multiple of half the wavelength of the first electromagnetic radiation.

### CROSS-REFERENCE TO RELATED APPLICATIONS

This patent application is a national phase filing under section 371 of PCT/EP2022/083493, filed Nov. 28, 2022, which claims the priority of German patent application 102021133999.5, filed Dec. 21, 2021, each of which is incorporated herein by reference in its entirety.

### TECHNICAL FIELD

An optoelectronic semiconductor component and an optoelectronic arrangement are disclosed. The optoelectronic semiconductor component and the optoelectronic arrangement are in particular configured to generate electromagnetic radiation in the spectral range between infrared radiation and UV radiation, in particular visible light.

### SUMMARY

Embodiments provide an optoelectronic semiconductor component which exhibits improved efficiency.

Further embodiments provide an optoelectronic arrangement which exhibits improved efficiency. The optoelectronic arrangement comprises at least two optoelectronic semiconductor components.

According to at least one embodiment, the optoelectronic semiconductor component comprises at least one lamella having a longitudinal axis extending along an imaginary straight line. In the present case, a lamella is an elongated structure that extends along an imaginary straight line. Within the manufacturing tolerance, the lamella can be axially symmetrical to the longitudinal axis.

For example, the lamella has two side surfaces that are arranged opposite each other. The two side surfaces can be symmetrical to the longitudinal axis of the lamella within the manufacturing tolerance.

According to at least one embodiment, the optoelectronic semiconductor component comprises an electrically conductive main body with a recess. The main body comprises a first side and a side opposite the first side. In particular, the recess extends from the first side in the direction of the second side into the main body. For example, an electrical connection of the lamella is made at least partially via the main body.

According to at least one embodiment of the optoelectronic semiconductor component, the lamella comprises a first semiconductor region of a first conductivity, a second semiconductor region of a second conductivity and an active region arranged between the first and the second semiconductor region, which is configured to emit a first electromagnetic radiation. The first electromagnetic radiation has a first wavelength. The first wavelength is to be understood here and in the following as a main wavelength of the first electromagnetic radiation. A main wavelength of a radiation is to be understood here and in the following as the wavelength at which a spectrum of the electromagnetic radiation has a global intensity maximum.

Preferably, the first conductivity differs from the second conductivity. The first conductivity is, for example, a p-type conductivity and the second conductivity is, in particular, an n-type conductivity or vice versa.

For example, the first semiconductor region is at least partially embedded in the second semiconductor region. In other words, the second semiconductor region at least partially surrounds the first semiconductor region. The side surfaces of the lamella are preferably formed by the second semiconductor region. In particular, a cover surface and end faces of the lamella are formed by the second semiconductor region. The cover surface connects the two side surfaces of the lamella and is preferably aligned parallel to the main extension plane of the main body. The end faces connect the side surfaces of the lamella and are aligned, for example, transversely, in particular perpendicularly, to the main extension plane of the main body.

The active region preferably comprises a p-n junction, a double heterostructure, a single quantum well (SQW) or a multi-quantum well (MQW) for the generation of radiation. The term quantum well structure has no meaning with regard to the dimensionality of the quantization. It therefore includes quantum wells, quantum wires and quantum dots and any combination of these structures.

For example, an active region is arranged on each of the side surfaces of the lamella. The active region is the function-bearing region of the optoelectronic semiconductor component. This means that the electromagnetic radiation to be generated is produced in this active region during operation of the optoelectronic semiconductor component. In particular, it is possible for the active region to be formed in the same way on each side surface within the manufacturing tolerance. This means, for example, that the active regions on each side surface generate electromagnetic radiation in the same wavelength range within the manufacturing tolerance.

For example, the active regions of a lamella are produced simultaneously in the same manufacturing process. The active regions of a lamella are electrically conductively connected to each other. The active regions can be physically connected to each other so that the lamella has a single active region that extends from one side surface of the lamella to the other side surface of the lamella via a further surface, for example the cover surface or an end surface of the lamella. Furthermore, it is possible that the active regions of each side surface of the lamella are not physically connected to each other, so that the lamella has exactly one active region on each side surface. For example, the active regions of the lamella can be electrically connected in parallel to one another via other components of the lamella or of the optoelectronic semiconductor component.

According to at least one embodiment of the optoelectronic semiconductor component, the lamella is at least partially arranged in the recess. For example, the recess is not completely filled by the lamella. In particular, the recess extends only partially along a length and/or a depth of the recess.

According to at least one embodiment of the optoelectronic semiconductor component, the lamella has a length along its longitudinal axis which, within a manufacturing tolerance, corresponds to half the wavelength or an integer multiple of half the wavelength of the first electromagnetic radiation. In particular, this results in a resonance between the electromagnetic radiation emitted by the lamella and the length of the lamella. In particular, the length of the lamella is selected such that it enables the lamella to function as a slot antenna whose antenna resonance lies in the range of the electromagnetic wavelength to be emitted. This advantageously increases the probability of the spontaneous recombination rate in the semiconductor material of the lamella and non-radiative recombination mechanisms are advantageously reduced or suppressed. The wavelength of the emitted electromagnetic radiation is influenced, among other things, by the length of the lamella. This enables an advantageously stable wavelength against external environmental influences, for example a change in temperature or modulation of an operating current.

Preferably, the lamella is based on a III/V semiconductor compound material. A III/V semiconductor compound material has at least one element from the third main group, such as B, Al, Ga, In, and one element from the fifth main group, such as N, P, As. In particular, the term “III/V compound semiconductor compound material” comprises the group of binary, ternary or quaternary compounds which contain at least one element from the third main group and at least one element from the fifth main group, for example nitride and phosphide compound semiconductors. Such a binary, ternary or quaternary compound may also have, for example, one or more dopants and additional components.

In particular, the lamella is based on a nitride compound semiconductor material, a phosphide compound semiconductor material or an arsenide compound semiconductor material.

“Based on nitride semiconductor compound material” in the present context means that the lamella or at least a part thereof, particularly preferably at least the active region and/or a growth substrate wafer, comprises or consists of a nitride semiconductor compound material, preferably Aln Gam In1-n-m N, where 0≤n≤1, 0≤m≤1 and n+m≤1. This material does not necessarily have to have a mathematically exact composition according to the above formula. Rather, it can, for example, have one or more dopants as well as additional components. For the sake of simplicity, however, the above formula only contains the essential components of the crystal lattice (Al, Ga, In, N), even if these may be partially replaced and/or supplemented by small amounts of other substances.

“Based on phosphide semiconductor compound material” in this context means that the lamella or at least a part thereof, particularly preferably at least the active region and/or a growth substrate wafer, preferably comprises Alₙ Gaₘ In₁₋ₙ₋ₘ P or Asₙ Gaₘ In₁₋ₙ₋ₘ P, where 0≤n≤1, 0≤m≤1 and n+m≤1. This material does not necessarily have to have a mathematically exact composition according to the above formula. Rather, it can have one or more dopants as well as additional components. For the sake of simplicity, however, the above formula only contains the essential components of the crystal lattice (Al or As, Ga, In, P), even if these may be partially replaced by small amounts of other substances.

“Based on arsenide semiconductor compound material” in this context means that the lamella or at least a part thereof, particularly preferably at least the active region and/or a growth substrate wafer, preferably comprises Alₙ Gaₘ In₁₋ₙ₋ₘ As, where 0≤n≤1, 0≤m≤1 and n+m≤1. This material does not necessarily have to have a mathematically exact composition according to the above formula. Rather, it can have one or more dopants as well as additional components. For the sake of simplicity, however, the above formula only contains the essential components of the crystal lattice (Al or As, Ga, In), even if these may be partially replaced by small amounts of other substances.

According to at least one embodiment, the optoelectronic semiconductor component comprises
at least one lamella, with a longitudinal axis extending along an imaginary straight line, and
an electrically conductive main body with a recess, wherein
the lamella comprises a first semiconductor region of a first conductivity, a second semiconductor region of a second conductivity and an active region arranged between the first and the second semiconductor region, which is configured to emit a first electromagnetic radiation,
the lamella is at least partially arranged in the recess,
the lamella has a length along its longitudinal axis which, within a manufacturing tolerance, corresponds to half the wavelength or an integer multiple of half the wavelength of the first electromagnetic radiation.

An optoelectronic semiconductor component described here is based, among other things, on the following considerations: In future optoelectronic semiconductor components, ever smaller dimensions will be sought. Therefore, higher pixel densities of display systems can be achieved for example. Smaller dimensions can have a negative impact on optical efficiency due to an increased non-radiative recombination probability. Furthermore, it is difficult to achieve the desired radiation characteristics with ever smaller components.

The optoelectronic semiconductor component described here makes use, among other things, of the idea of arranging an active region in the form of a lamella in a recess in an electrically conductive main body. As a result, a length of the lamella can be advantageously selected which enables the lamella to function as a slot antenna whose antenna resonance lies in the range of an electromagnetic wavelength to be emitted. Such a design of an optoelectronic semiconductor component increases, for example, a spontaneous recombination rate in the lamella, which results in an advantageous reduction of a non-radiating recombination rate and makes it possible to realize a particularly short switch-on time. Furthermore, an optoelectronic semiconductor component designed in this way can be controlled with particularly simple driver circuits, as an emitted wavelength is particularly insensitive to the influence of current modulation and also to a change in temperature.

According to at least one embodiment of the optoelectronic semiconductor component, the lamella has a width of less than 100 nm, preferably less than 30 nm. The width of the lamella corresponds here and in the following to the smallest expansion of the lamella, measured between its side surfaces. A small width enables a particularly high antenna gain, for example.

According to at least one embodiment of the optoelectronic semiconductor component, the lamella has a height that is at least a factor of 2 smaller than the wavelength of the first electromagnetic radiation. The height of the lamella corresponds here and in the following to a smallest expansion of the lamella, measured between its cover surface and an outer surface of the lamella opposite the cover surface. The height of the lamella is advantageously smaller than the first wavelength and greater than the width of the lamella. In particular, a ratio of height to width of the lamella is at least 2. The height of the lamella is in particular smaller than the length of the lamella.

According to at least one embodiment of the optoelectronic semiconductor component, the first semiconductor region has a width of at most 30 nm, preferably of at most 10 nm. A particularly narrow first semiconductor region enables a high optical efficiency of the optoelectronic semiconductor component.

According to at least one embodiment of the optoelectronic semiconductor component, a distance between a cover surface of the lamella and a bottom surface of the recess is optimized for maximum reflection. In particular, a distance between a section of the active region arranged below the cover surface and a bottom surface of the recess is optimized for maximum reflection. For example, the distance is selected such that an electromagnetic wave emitted by the active region is reflected with a phase shift of an integer multiple of 2π.

According to at least one embodiment of the optoelectronic semiconductor component, a plurality of lamellas is arranged in the main body. In particular, each lamella is arranged in its own recess in the main body. A plurality of lamellas enables an increase in optical output power and can advantageously create redundancy of the individual lamellas.

According to at least one embodiment of the optoelectronic semiconductor component, all lamellas are aligned parallel to each other. Parallel here and in the following means parallel within the scope of a manufacturing tolerance. In particular, a certain inhomogeneous radiation characteristic is generated by aligning all the lamellas in parallel. For example, a preferred polarization of the emitted electromagnetic radiation is generated by the parallel alignment of the lamellas.

According to at least one embodiment of the optoelectronic semiconductor component, at least one lamella is aligned transversely, in particular perpendicular to at least one other lamella. Advantageously, a radiation characteristic of the optoelectronic semiconductor component can thus be homogenized. In particular, a degree of polarization of the emitted electromagnetic radiation can be reduced.

According to at least one embodiment of the optoelectronic semiconductor component, all lamellas have the same length. Equal here and in the following means equal in the context of a manufacturing tolerance. Advantageously, an equal length of all lamellas enables the emission of electromagnetic radiation in a narrow spectral range.

According to at least one embodiment of the optoelectronic semiconductor component, the main body is formed with a metal. For example, the main body is formed with at least one of the following metals: Au, Ag, Al, Ti, Pt. In particular, the main body is formed with a metal alloy. Metals advantageously exhibit particularly high electric conductivity and high optical reflectivity. High electric conductivity enhances the antenna effect of the main body. A high optical reflectivity increases the proportion of electromagnetic radiation reflected in the recess and thus also the optical efficiency of the optoelectronic semiconductor component.

According to at least one embodiment of the optoelectronic semiconductor component, an electrically insulating element is arranged downstream of the lamella, wherein the first semiconductor region is at least partially free of the insulating element. For example, the insulating element is formed with at least one of the following materials: silicon oxide, silicon nitride, titanium oxide, tantalum oxide. Alternatively, the insulating element is formed with an undoped or a defective semiconductor material. In particular, the insulating element has a thickness of less than 10 μm, preferably less than 1 μm. The thickness of the insulating element corresponds to a maximum expansion of the insulating element in a direction transverse to the main extension plane of the insulating element. Advantageously, the insulating element is at least partially permeable to the electromagnetic radiation emitted in the optoelectronic semiconductor component during operation. Preferably, side surfaces of the main body are covered by the insulating element.

According to at least one embodiment of the optoelectronic semiconductor component, the first semiconductor region is electrically contacted by a radiation permeable contact element. The contact element is arranged downstream of the insulating element, for example. In other words, the insulating element is preferably arranged between the contact element and the main body. In particular, the contact element is formed with a radiation permeable, electrically conductive material. For example, the contact element is formed with indium tin oxide (ITO).

According to at least one embodiment of the optoelectronic semiconductor component, an optical element is arranged downstream of the optoelectronic semiconductor component in an emission direction. The optical element is, for example, a roughening, an anti-reflective layer, a color filter or a lens. In particular, the optical element is a microlens, a cylindrical lens or a META structure. Preferably, the optical element is arranged directly downstream of the contact element.

An optoelectronic arrangement is further disclosed. In particular, the optoelectronic arrangement comprises an optoelectronic semiconductor component described herein. That is, all features disclosed in connection with the optoelectronic semiconductor component are also disclosed for the optoelectronic arrangement and vice versa.

According to at least one embodiment, the optoelectronic arrangement comprises a plurality of optoelectronic semiconductor components, wherein at least a first optoelectronic semiconductor component for emitting a first wavelength,
at least a second optoelectronic semiconductor component for emitting a second wavelength, and
at least a third optoelectronic semiconductor component is configured to emit a third wavelength. In particular, the first, second and third wavelengths differ from each other. Advantageously, a multicolor emitting optoelectronic arrangement can thus be provided.

According to at least one embodiment of the optoelectronic arrangement, the first wavelength is in the red spectral range,
the second wavelength in the green spectral range and
the third wavelength in the blue spectral range. An optoelectronic arrangement designed in this way can advantageously be used to provide a color-emitting RGB pixel of a display arrangement.

According to at least one embodiment of the optoelectronic arrangement, the main bodies of at least two semiconductor components are designed continuously. In other words, at least two semiconductor components are arranged in an integrally formed main body. In addition to simplified manufacturability, a one-piece main body can result in improved cooling of the optoelectronic arrangement.

According to at least one embodiment of the optoelectronic arrangement, an optical separation structure is arranged between at least two directly adjacent semiconductor components. The separating structure is formed, for example, with a metal or a polymer. By means of the separating structure, optical crosstalk between neighboring optoelectronic semiconductor components can be reduced or prevented. Advantageously, the optical separation structure improves an optical contrast ratio between neighboring optoelectronic semiconductor components.

According to at least one embodiment of the optoelectronic arrangement, a distance between directly adjacent semiconductor components is at most 5 μm, preferably at most 1 μm. A small distance between neighboring semiconductor components advantageously results in a particularly high density of semiconductor components and thus, for example, of subsequent pixels in a display.

According to at least one embodiment of the optoelectronic arrangement, the semiconductor components are arranged on a common substrate, wherein the substrate comprises integrated circuits for controlling the optoelectronic semiconductor components. The substrate is formed with silicon, for example. Preferably, all optoelectronic semiconductor components can be controlled individually and independently of one another by means of the integrated circuits.

According to at least one embodiment of the optoelectronic arrangement, a radiation permeable contact element extends over at least two optoelectronic semiconductor components. For example, the contact element is formed with indium tin oxide. In particular, the contact element forms a common anode or a common cathode for at least two optoelectronic semiconductor components.

According to at least one embodiment of the optoelectronic arrangement, the first, second and third semiconductor components are each formed with different semiconductor materials. In particular, the lamellas in the first, second and third semiconductor components are each formed with different semiconductor materials. For example, the lamellas in the first semiconductor components are formed with a semiconductor material whose bandgap is in the range of the first wavelength, the lamellas in the second semiconductor components are formed with a semiconductor material whose bandgap is in the range of the second wavelength, and the lamellas in the third semiconductor components are formed with a semiconductor material whose bandgap is in the range of the third wavelength.

An optoelectronic semiconductor component described herein and an optoelectronic arrangement described herein are particularly suitable for use as compact light sources in displays or projection applications, for example in head-up displays, augmented displays or virtual reality displays.

### BRIEF DESCRIPTION OF THE DRAWINGS

Further advantages and advantageous configurations and further embodiments of the optoelectronic semiconductor component and the optoelectronic arrangement result from the following embodiments shown in connection with the figures.

FIG. 1 shows a schematic angled view of an optoelectronic semiconductor component described here according to a first exemplary embodiment;

FIG. 2 shows a schematic sectional view of an optoelectronic semiconductor component described herein according to a second exemplary embodiment;

FIGS. 3A and 3B show schematic sectional views of an optoelectronic arrangement described herein according to a first exemplary embodiment;

FIGS. 4A to 4C show schematic sectional views and a schematic top view of an optoelectronic semiconductor component described herein according to a third exemplary embodiment;

FIG. 5 shows a schematic top view of an optoelectronic arrangement described herein according to a second exemplary embodiment;

FIG. 6 shows a schematic top view of an optoelectronic semiconductor component described herein according to a fourth exemplary embodiment;

FIG. 7 shows a schematic top view of an optoelectronic semiconductor component described herein according to a fifth exemplary embodiment;

FIGS. 8A and 8B show schematic sectional views of an optoelectronic semiconductor component described herein according to a sixth exemplary embodiment;

FIG. 9 shows a schematic sectional view of an optoelectronic arrangement described herein according to a third exemplary embodiment;

FIG. 10 shows a schematic sectional view of an optoelectronic semiconductor component described herein according to a seventh embodiment; and

FIG. 11 shows graphs of a spectral intensity distribution of a p-n junction without an antenna, an antenna resonance and a spectral intensity distribution of a p-n junction with an antenna.

### DETAILED DESCRIPTION OF ILLUSTRATIVE EMBODIMENTS

Elements that are identical, similar or have the same effect are marked with the same reference symbols in the figures. The figures and the proportions of the elements shown in the figures are not to be regarded as being to scale. Rather, individual elements may be shown in exaggerated size for better visualization and/or better comprehensibility.

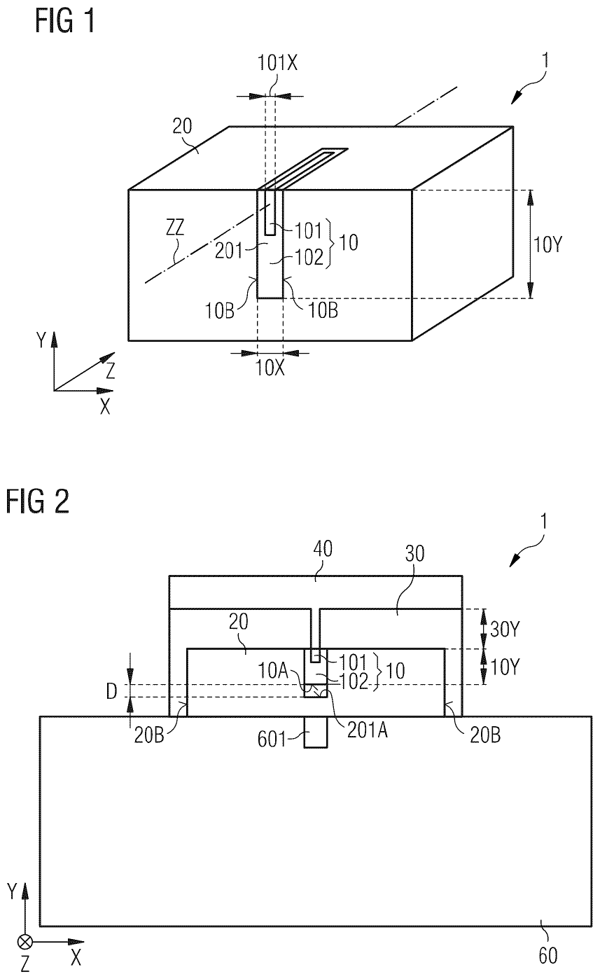

FIG. 1 shows a schematic angled view of an optoelectronic semiconductor component 1 described herein according to a first exemplary embodiment. The optoelectronic semiconductor component 1 comprises a lamella 10 with a first semiconductor region 101 of a first conductivity, a second semiconductor region 102 of a second conductivity and an active region 103 arranged between the first and second semiconductor regions 101, 102. The first conductivity is a p-type conductivity and the second conductivity is an n-type conductivity. Consequently, the first region 101 is an anode terminal of the lamella 10. In operation, the active region 103 is configured to emit a first electromagnetic radiation. The active region 103 is not shown here and in the following FIGS. 2 to 9 for improved clarity.

The lamella 10 comprises a longitudinal axis ZZ, which extends along an imaginary straight line, a width 10X and a height 10Y. The width 10X of the lamella 10 corresponds to a smallest expansion of the lamella 10, measured between its side surfaces 10B. The height 10Y of the lamella 10 is at least a factor of 2 smaller than the wavelength of the first electromagnetic radiation. The width 10X of the lamella is less than 30 nm. Furthermore, the first semiconductor region 101 has a width 101X of less than 10 nm.

Furthermore, the optoelectronic semiconductor component 1 comprises an electrically conductive main body 20 with a recess 210. The lamella 10 is arranged completely in the recess 210 of the main body 20. The lamella 10 has a length 10Z along its longitudinal axis ZZ which, within a manufacturing tolerance, corresponds to half the wavelength or an integer multiple of half the wavelength of the first electromagnetic radiation. The main body 20 is formed with a metal. The electrical connection of the second semiconductor region 102 is made via the main body 20. In particular, the optoelectronic semiconductor component 1 is controlled by means of analog current modulation.

FIG. 2 shows a schematic sectional view of an optoelectronic semiconductor component 1 described here according to a second exemplary embodiment. The second exemplary embodiment essentially corresponds to the first exemplary embodiment shown in FIG. 1. In contrast to the first exemplary embodiment, the optoelectronic semiconductor component 1 comprises an electrically insulating element 30 and a radiation permeable contact element 40. Furthermore, the optoelectronic semiconductor component 1 is arranged on a substrate 60.

The first semiconductor region 101 is at least partially free of the insulating element 30. The insulating element 30 is formed, for example, with at least one of the following materials: silicon oxide, silicon nitride, titanium oxide, tantalum oxide. Alternatively, the insulating element 30 is formed with an undoped or a defective semiconductor material. In particular, the insulating element 30 has a thickness 30Y of less than 1 μm. The thickness 30Y of the insulating element 30 corresponds to a largest expansion of the insulating element in a direction transverse to the main extension plane of the insulating element 30. The insulating element 30 is at least partially permeable to the electromagnetic radiation emitted in the optoelectronic semiconductor component 1 during operation. Preferably, side surfaces 20B of the main body 20 are covered by the insulating element 30. In particular, the side surfaces 20B of the main body are completely covered by the insulating element 30.

The contact element 40 makes electrical contact with the first semiconductor region 101 through an opening in the insulating element 30. The contact element 40 is arranged downstream of the insulating element 30. In other words, the insulating element 30 is arranged between the contact element 40 and the main body 20. The contact element 40 is formed with a radiation permeable, electrically conductive material. For example, the contact element 40 is formed with indium tin oxide (ITO).

The substrate 60 comprises integrated circuits 601 for driving the optoelectronic semiconductor component 1. The substrate 60 is formed with silicon.

The lamella 10 embedded in the main body 20 only partially fills the recess 210. This results in a distance D between a cover surface 10A of the lamella 10 and a bottom surface 201A of the recess 201. The distance D can be set such that a particularly high reflectivity results for electromagnetic radiation emitted from the active region 103 during operation, which strikes the bottom surface 201A of the recess 202. Thus, an optical efficiency of the optoelectronic semiconductor component may be advantageously increased.

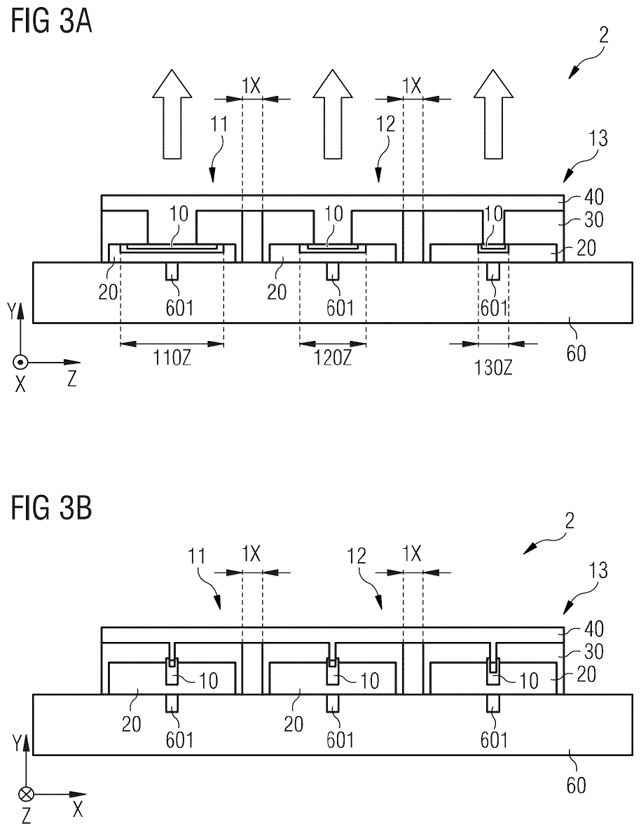

FIGS. 3A and 3B show schematic sectional views of an optoelectronic arrangement 2 described herein according to a first exemplary embodiment. The optoelectronic arrangement 2 comprises a first optoelectronic semiconductor component 11, which is configured to emit electromagnetic radiation with a first wavelength, a second optoelectronic semiconductor component 12, which is configured to emit electromagnetic radiation with a second wavelength, a third optoelectronic semiconductor component 13, which is configured to emit electromagnetic radiation with a third wavelength.

The first wavelength is in the red spectral range,
the second wavelength is in the green spectral range and
the third wavelength is in the blue spectral range. With an optoelectronic arrangement configured in this way, the optoelectronic arrangement 2 can advantageously represent a multicolor emitting RGB pixel of a display arrangement. The first optoelectronic semiconductor component 11 has a lamella 10 with a first length 110Z, which is formed with a first semiconductor material. The second optoelectronic semiconductor component 12 has a lamella 10 with a second length 120Z, which is formed with a second semiconductor material. The third optoelectronic semiconductor component 13 has a lamella 10 with a third length 130Z, which is formed with a third semiconductor material. The lengths of the lamellas and the first, second and third semiconductor materials are each matched to the electromagnetic radiation to be emitted. The first length 110Z is greater than the second length 120Z and the second length 120Z is greater than the third length 130Z. The bandgap of the first semiconductor material is smaller than the bandgap of the second semiconductor material and the bandgap of the second semiconductor material is smaller than the bandgap of the third semiconductor material.

All semiconductor components 11, 12, 13 are arranged on a common substrate 60, wherein the substrate 60 comprises integrated circuits 601 for controlling the optoelectronic semiconductor components 11, 12, 13. By means of the integrated circuits 601, all optoelectronic semiconductor components 11, 12, 13 can be controlled individually and independently of each other. All semiconductor components 11, 12, 13 are electrically contacted via a common radiation permeable contact element 40. The contact element 40 thus forms a common anode or cathode for the first, second and third optoelectronic semiconductor components 11, 12, 13.

The semiconductor components 11, 12, 13 are each arranged at a distance 1X from one another which is at most 5 μm, preferably at most 1 μm. The small distance 1X advantageously enables a particularly high density of semiconductor components 11, 12, 13 on a given lateral area.

Alternatively, the main bodies 20 of at least two semiconductor components 1 are formed continuously. In other words, at least two semiconductor components 1 are arranged in an integrally formed main body 20. In addition to simplified manufacturability, a one-piece main body 20 can result in improved cooling of the optoelectronic arrangement 2.

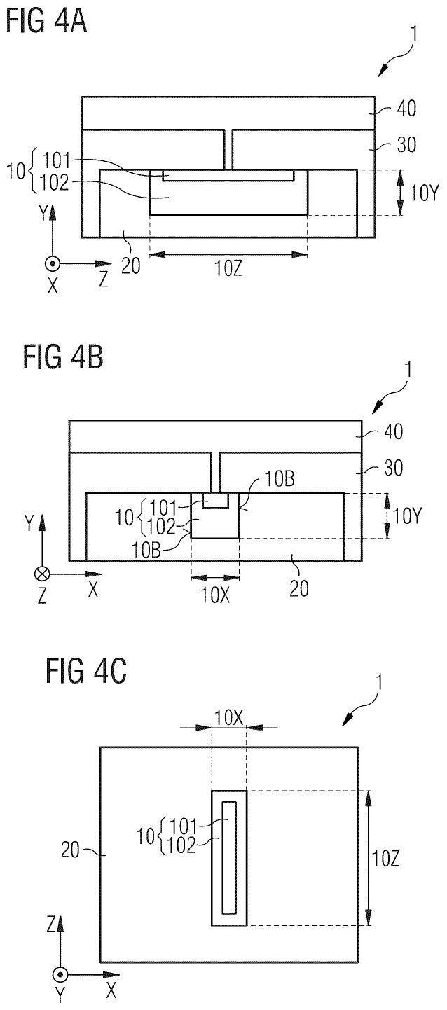

FIGS. 4A to 4C show schematic sectional views and a schematic top view of an optoelectronic semiconductor component 1 described herein according to a third exemplary embodiment. The third exemplary embodiment essentially corresponds to the second exemplary embodiment shown in FIG. 2. In contrast to the second exemplary embodiment, the recess 202 is completely filled by the lamella 10.

The lamella 10 comprises a first semiconductor region 101 of a first conductivity, a second semiconductor region 102 of a second conductivity and an active region 103 arranged between the first and second semiconductor regions 101, 102, which is not shown.

The width 10X of the lamella 10 corresponds to a smallest expansion of the lamella 10, measured between its side surfaces 10B. The height 10Y of the lamella 10 is at least a factor of 2 smaller than the wavelength of the first electromagnetic radiation. The width 10X of the lamella is less than 30 nm. Furthermore, the lamella 10 has a length 10Z which, within a manufacturing tolerance, corresponds to half the wavelength or an integer multiple of half the wavelength of the first electromagnetic radiation.

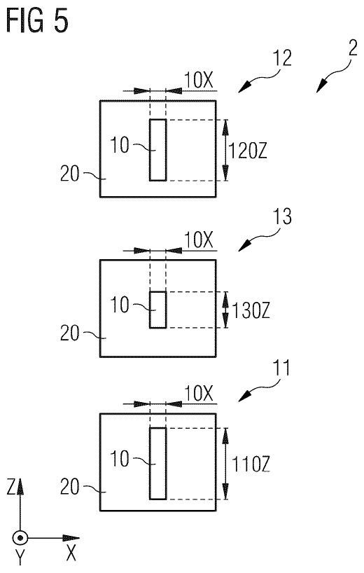

FIG. 5 shows a schematic top view of an optoelectronic arrangement 2 described here according to a second exemplary embodiment. The second exemplary embodiment essentially corresponds to the first exemplary embodiment shown in FIGS. 3A and 3B. In contrast to the first exemplary embodiment, the optoelectronic arrangement 2 is shown without a substrate 60 and in a top view, and the optoelectronic semiconductor components 1 are arranged in a different order.

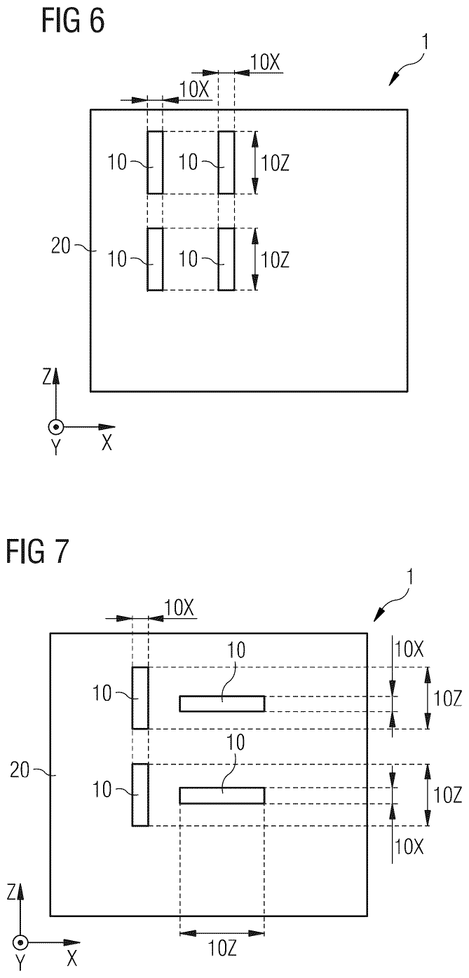

FIG. 6 shows a schematic top view of an optoelectronic semiconductor component 1 described herein according to a fourth exemplary embodiment. The fourth exemplary embodiment essentially corresponds to the third exemplary embodiment shown in FIGS. 4A to 4C. In contrast to the third exemplary embodiment, a plurality of lamellas 10 are arranged in a plurality of recesses 201 in a main body 20. All lamellas have an identical length 10Z within a manufacturing tolerance and are formed with the same semiconductor material. For example, the lamellas 10 are designed as redundant emitters of a part of a pixel. All lamellas 10 are intended to emit electromagnetic radiation with an identical wavelength.

All lamellas 10 are aligned parallel to each other. This results in a particularly high degree of polarization of the emitted electromagnetic radiation. Furthermore, a radiation characteristic in the far field is particularly inhomogeneous.

FIG. 7 shows a schematic top view of an optoelectronic semiconductor component 1 described here according to a fifth exemplary embodiment. The fifth exemplary embodiment essentially corresponds to the fourth exemplary embodiment shown in FIG. 6. In contrast to the fourth exemplary embodiment, one half of the lamellas are aligned transversely, in particular perpendicular to another half of the lamellas 10. This advantageously results in a particularly low degree of polarization of an emitted electromagnetic radiation and a particularly homogeneous radiation characteristic in the far field.

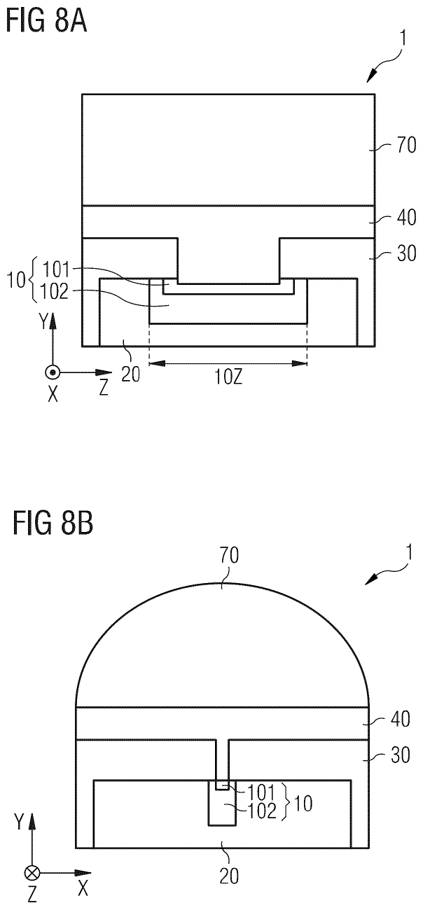

FIGS. 8A and 8B show schematic sectional views of an optoelectronic semiconductor component 1 described herein according to a sixth exemplary embodiment. The sixth exemplary embodiment essentially corresponds to the third exemplary embodiment shown in FIGS. 4A to 4C. In contrast to the third exemplary embodiment, an optical element 70 is arranged downstream of the contact element 40. The optical element 70 is a cylindrical lens that influences a radiation characteristic of the optoelectronic semiconductor component 1 in the far field. For example, the optical element 70 is arranged directly on the contact element 40.

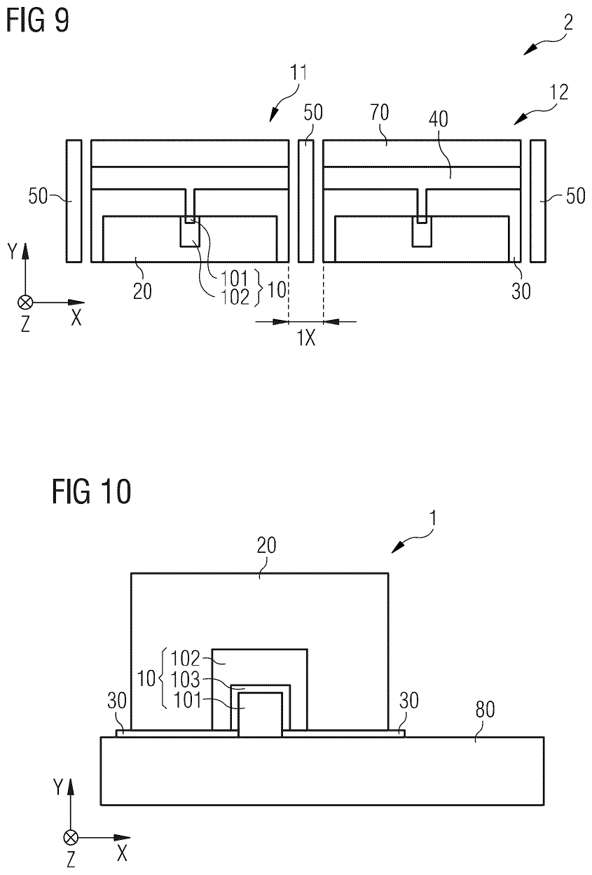

FIG. 9 shows a schematic sectional view of an optoelectronic arrangement 2 described here according to a third exemplary embodiment. The third exemplary embodiment essentially corresponds to the first exemplary embodiment shown in FIGS. 3A and 3B. In contrast to the first exemplary embodiment, optical separation structures 50 are arranged in each case between two adjacent optoelectronic semiconductor components. The separating structures 50 are formed with a metal or a polymer. By means of the separating structures 50, optical crosstalk between neighboring optoelectronic semiconductor components 1 can be reduced or prevented.

Furthermore, an optical element 70 is arranged downstream of each of the semiconductor components 1. The optical element 70 comprises a color filter, which is intended to filter electromagnetic radiation emitted by the optoelectronic semiconductor components 1 during operation. Advantageously, a spectrally particularly narrow-band electromagnetic radiation can thus be emitted.

FIG. 10 shows a schematic sectional view of an optoelectronic semiconductor component 1 described herein according to a seventh exemplary embodiment. The optoelectronic semiconductor component 1 comprises a lamella 10 with a first semiconductor region 101, a second semiconductor region 102 and an active region 103 arranged between the first and second semiconductor regions 101, 102.

In a method for manufacturing the optoelectronic semiconductor component 1, the first region 101 is first grown on a growth substrate 80. The growth substrate 80 is formed, for example, with a sapphire. An insulating element 30 is then arranged on the growth substrate 80 and laterally next to the first region 101. The active region 103 is then deposited on the first region 101, the second region 102 on the active region 103 and the main body 20 on the second region 102.

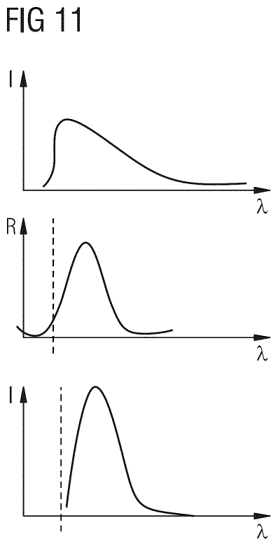

FIG. 11 shows a spectral intensity distribution of a p-n junction without an antenna in an upper graph, an antenna resonance in a middle graph and a spectral intensity distribution of a p-n junction with an antenna in a lower graph. The spectral intensity distribution of a p-n junction without an antenna has a wide offshoot towards longer wavelengths. The antenna resonance has a spectrally narrow distribution. The spectral intensity distribution of the p-n junction with an antenna results from a mathematical convolution of the spectral intensity distribution of a p-n junction without an antenna with the antenna resonance.

The invention is not limited by the description based on the embodiments. Rather, the invention includes any new feature as well as any combination of features, which includes in particular any combination of features in the patent claims, even if this feature or combination itself is not explicitly stated in the patent claims or embodiments.

1-19. (canceled)

20. An optoelectronic semiconductor component comprising:
at least one lamella with a longitudinal axis extending along an imaginary straight line; and
an electrically conductive main body with a recess,
wherein the lamella comprises a first semiconductor region of a first conductivity, a second semiconductor region of a second conductivity and an active region arranged between the first and the second semiconductor region, the active region being configured to emit a first electromagnetic radiation,
wherein the lamella is arranged at least partially in the recess, and
wherein the lamella has a length along the longitudinal axis which, within a manufacturing tolerance, corresponds to half a wavelength or an integer multiple of half the wavelength of the first electromagnetic radiation.

21. The optoelectronic semiconductor component according to claim 20, wherein the lamella has a width of less than 100 nm.

22. The optoelectronic semiconductor component according to claim 20, wherein the lamella has a height, which is at least a factor of 2 smaller than the wavelength of the first electromagnetic radiation.

23. The optoelectronic semiconductor component according to claim 20, wherein the first semiconductor region has a width of at most 30 nm.

24. The optoelectronic semiconductor component according to claim 20, wherein a distance between a cover surface of the lamella and a bottom surface of the recess is optimized for maximum reflection.

25. The optoelectronic semiconductor component according to claim 20, wherein a plurality of lamellas is arranged in the main body.

26. The optoelectronic semiconductor component according to claim 25, wherein all lamellas are aligned parallel to each other.

27. The optoelectronic semiconductor component according to claim 25, wherein at least one lamella is aligned transversely to at least one further lamella.

28. The optoelectronic semiconductor component according to claim 25, wherein all lamellas have the same length.

29. The optoelectronic semiconductor component according to claim 20, wherein the main body comprises a metal.

30. The optoelectronic semiconductor component according to claim 20, further comprising an electrically insulating element arranged downstream of the lamella, wherein the first semiconductor region is at least partially free of the insulating element.

31. The optoelectronic semiconductor component according to claim 20, wherein the first semiconductor region is electrically contacted by a radiation permeable contact element.

32. An optoelectronic arrangement comprising:
a plurality of optoelectronic semiconductor components according to claim 20,
wherein at least a first optoelectronic semiconductor component is configured to emit a first wavelength,
wherein at least a second optoelectronic semiconductor component is configured to emit a second wavelength, and
wherein at least a third optoelectronic semiconductor component is configured to emit a third wavelength.

33. The optoelectronic arrangement according to claim 32,
wherein the first wavelength is in a red spectral range,
wherein the second wavelength is in a green spectral range, and
wherein the third wavelength is in a blue spectral range.

34. The optoelectronic arrangement according to claim 32, wherein the main bodies of at least two semiconductor components are formed continuously.

35. The optoelectronic arrangement according to claim 32, further comprising an optical separation structure arranged between at least two directly adjacent semiconductor components.

36. The optoelectronic arrangement according to claim 32, wherein a distance between immediately adjacent semiconductor components is at most 5 μm.

37. The optoelectronic arrangement according to claim 32, wherein the semiconductor components are arranged on a common substrate, the substrate comprising integrated circuits configured to drive the optoelectronic semiconductor components.

38. The optoelectronic arrangement according to claim 32, further comprising a radiation permeable contact element extending over at least two optoelectronic semiconductor components.
